(19) United States
(12) Patent Application Publication
(10) Pub. No.: US 2022/0243094 A1
(43) Pub. Date: Aug. 4, 2022

(54) SILICON CARBONITRIDE POLISHING COMPOSITION AND METHOD

(71) Applicant: CMC Materials, Inc., Aurora, IL (US)

(72) Inventors: Lung-Tai LU, Tainan City (TW); Brian Reiss, Woodridge, IL (US); Roman A. Ivanov, Aurora, IL (US)

(21) Appl. No.: 17/592,612

(22) Filed: Feb. 4, 2022

Related U.S. Application Data
(60) Provisional application No. 63/145,842, filed on Feb. 4, 2021.

(51) Int. Cl. C09G 1/04; C09G 1/02; H01L 21/321

(52) U.S. Cl. CPC C09G 1/04; B82Y 40/00; H01L 21/3212; C09G 1/02

(57) ABSTRACT

A chemical mechanical polishing composition for polishing a substrate including a silicon carbonitride layer, the composition comprising, consisting essentially of, or consisting of a water based liquid carrier, anionic colloidal silica particles dispersed in the liquid carrier, a topography control agent, and having a pH in a range from about 2 to about 7.

### FIELD OF THE INVENTION

The disclosed embodiments relate to chemical mechanical polishing and more particularly relate to compositions and methods for polishing substrates including a silicon carbonitride layer.

### BACKGROUND OF THE INVENTION

Silicon carbonitride (SiCN) dielectrics are increasingly used in semiconductor devices, for example, as dielectric layers, diffusion barriers, and stopping layers. The use of SiCN can provide numerous advantages especially as the device size shrinks. For example, SiCN generally has a lower dielectric constant than SiN and may therefore enable the layer to have a lower capacitance.

One difficulty with SiCN integration is achieving suitable chemical mechanical polishing (CMP) performance. For example, achieving a suitable SiCN removal rate and meeting topography metrics can be challenging. With the emergence of SiCN films in advanced semiconductor devices there is a need in the art for polishing compositions and methods that provide both a suitably high SiCN removal rate and suitable topography control.

### BRIEF SUMMARY OF THE INVENTION

A first chemical mechanical polishing composition for polishing a substrate including a silicon carbonitride layer is disclosed. The polishing composition comprises, consists essentially of, or consists of a water based liquid carrier, anionic colloidal silica particles dispersed in the liquid carrier, bis tris methane, and has a pH in a range from about 4 to about 7.

A second chemical mechanical polishing composition for polishing a substrate including a silicon carbonitride layer is disclosed. The polishing composition comprises, consists essentially of, or consists of a water based liquid carrier, anionic colloidal silica particles dispersed in the liquid carrier, acetic acid, and has a pH in a range from about 2.5 to about 4.

A method for polishing a substrate including a silicon carbonitride layer is further disclosed. The method may include contacting a wafer with the above described first or second polishing composition (or any one of the other compositions disclosed herein), moving the polishing composition relative to the wafer, and abrading the wafer to remove silicon carbonitride from the wafer and thereby polish the wafer.

### DETAILED DESCRIPTION OF THE INVENTION

Chemical mechanical polishing compositions are disclosed. One polishing composition comprises, consists essentially of, or consists of a water based liquid carrier, anionic colloidal silica particles dispersed in the liquid carrier, bis tris methane, and has a pH in a range from about 4 to about 7. Another polishing composition comprises, consists essentially of, or consists of a water based liquid carrier, anionic colloidal silica particles dispersed in the liquid carrier, acetic acid, and has a pH in a range from about 2.5 to about 4. Methods of using the disclosed compositions for polishing silicon carbonitride containing substrates are also disclosed.

The disclosed compositions and methods may provide various technical advantages and improvements over the prior art. For example, the disclosed compositions and methods may enable suitably high removal rates and improved topography control during a silicon carbonitride CMP operation.

The polishing composition generally contains abrasive particles suspended in a liquid carrier. The liquid carrier is used to facilitate the application of the abrasive particles and any optional chemical additives to the surface of the substrate to be polished (e.g., planarized). The liquid carrier comprises preferably consists of, or consists essentially of, deionized water.

The abrasive particles may include silica particles (such as fumed silica and/or colloidal silica particles) dispersed in the liquid carrier. Preferred embodiments include colloidal silica particles. As used herein the term colloidal silica particles refers to silica particles that are prepared via a wet process rather than the pyrogenic or flame hydrolysis process used to produce fumed silica, which are structurally different particles. The colloidal silica particles may be aggregated or non-aggregated. Non-aggregated particles are individually discrete particles that may be spherical or nearly spherical in shape, but can have other shapes as well (such as generally elliptical, square, or rectangular cross-sections). Aggregated particles are particles in which multiple discrete particles are clustered or bonded together to form aggregates having generally irregular shapes. Aggregated colloidal silica particles are disclosed, for example, in commonly assigned U.S. Pat. No. 9,309,442.

Most preferred embodiments advantageously include anionic colloidal silica particles. By “anionic” it is meant that the abrasive particles have a negative surface charge in the composition (e.g., at the pH of the composition). As is known to those of ordinary skill in the art, the charge on dispersed particles such as colloidal silica particles is commonly referred to in the art as the zeta potential (or the electrokinetic potential). The zeta potential of a particle refers to the electrical potential difference between the electrical charge of the ions surrounding the particle and the electrical charge of the bulk solution of the polishing composition (e.g., the liquid carrier and any other components dissolved therein). The zeta potential of a dispersion such as a polishing composition may be obtained using commercially available instrumentation such as the Zetasizer® available from Malvern® Instruments, the ZetaPlus Zeta Potential Analyzer available from Brookhaven Instruments, and/or an electro-acoustic spectrometer available from Dispersion Technologies, Inc.

In the disclosed polishing compositions, the anionic colloidal silica may have a negative charge (a negative zeta potential) of about 5 mV or more (e.g., about 10 mV or more, about 15 mV or more, or about 20 mV or more). The colloidal silica particles in the polishing composition may have a negative charge of about 50 mV or less. For example, the abrasive particles may have a zeta potential in a range from about negative 5 to about negative 50 mV (e.g., from about negative 10 to about negative 50 mV, from about negative 15 to about negative 45, or from about negative 20 to about negative 40).

Colloidal silica particles may be anionic in their natural state at the pH of the polishing composition. In preferred embodiments, the colloidal silica particles are rendered anionic at the pH of the polishing composition via surface metal doping and/or chemical surface treatment or partial surface treatment, for example, with an organic acid, a sulfur-based acid, a phosphorus-based acid, and/or an anionic polymer. Such treatment methodologies are known to those of ordinary skill in the art (e.g., as disclosed in U.S. Pat. No. 9,382,450).

The abrasive particles may have substantially any suitable particle size. The particle size of a particle suspended in a liquid carrier may be defined in the industry using various means. For example, the particle size may be defined as the diameter of the smallest sphere that encompasses the particle and may be measured using a number of commercially available instruments, for example, including the CPS Disc Centrifuge, Model DC24000HR (available from CPS Instruments, Prairieville, La.) or the Zetasizer® available from Malvern Instruments®. The abrasive particles may have an average particle size of about 25 nm or more (e.g., about 30 nm or more, about 40 nm or more, about 50 nm or more, or about 60 nm or more). The abrasive particles may have an average particle size of about 150 nm or less (e.g., about 125 nm or less, about 100 nm or less, or about 80 nm or less). Accordingly, the abrasive particles may have an average particle size in a range bounded by any two of the above endpoints. For example, the abrasive particles may have an average particle size in a range from about 25 nm to about 150 nm (e.g., from about 30 nm to about 125 nm, or from about 40 nm to about 100 nm). Preferred embodiments have a particle size in a range from about 50 nm to about 100 nm (with the most preferred range being from about 60 nm to about 80 nm).

The polishing composition may include substantially any suitable amount of the colloidal silica particles. The polishing composition may include about 0.1 wt. % or more colloidal silica particles at point of use (e.g., about 0.2 wt. % or more, about 0.5 wt. % or more, about 1 wt. % or more or about 2 wt. % or more). The polishing composition may also include about 20 wt. % or less of the colloidal silica particles at point of use (e.g., about 10 wt. % or less, about 8 wt. % or less, about 6 wt. % or less, or about 4 wt. % or less). Accordingly, the point of use amount of silica particles in the polishing composition may be in a range bounded by any two of the above endpoints. For example, the amount of colloidal silica particles in the polishing composition may be in a range from about 0.1 wt. % to about 20 wt. % (e.g., from about 0.5 wt. % to about 10 wt. %, or from about 0.5 wt. % to about 8 wt. %). Preferred embodiments have from about 1 wt. % to about 6 wt. % of the colloidal silica particles (with the most preferred embodiments having from about 2 wt. % to about 4 wt. % of the colloidal silica particles at point of use).

A first polishing composition generally has a mildly acidic or neutral pH of about 9 or less at point of use (e.g., about 8 or less, about 7 or less, or about 6 or less). The polishing composition may also have a pH of about 3 or more at point of use (e.g., about 4 or more or about 5 or more). Accordingly, the pH at point of use may be in a range bounded by any two of the above endpoints, for example from about 4 to about 8 (e.g., from about 4 to about 7 or from about 5 to about 6). In preferred embodiments the pH is in a range from about 5 to about 6 (and is most preferably about 5.5).

A second polishing composition is acidic having a pH of less than about 7 at point of use (e.g., about 6 or less, about 5 or less, or about 4 or less). The polishing composition may also have a pH of about 1 or more at point of use (e.g., about 2 or more or about 3 or more). Accordingly, the pH at point of use may be in a range bounded by any two of the above endpoints, for example from about 2 to about 6 (e.g., from about 2 to about 5 or from about 2.5 to about 4) In preferred embodiments the pH is in a range from about 3 to about 4 (and is most preferably about 3.5).

The polishing composition optionally includes pH adjusting agents, for example, potassium hydroxide, ammonium hydroxide, and/or nitric acid (depending, for example, on the desired pH). The polishing composition may also optionally include a pH buffering system, many of which are well-known in the art. The polishing composition may include any suitable amount of a pH adjustor and/or a pH buffering agent in order to achieve and/or maintain a desired pH (in either or both of a concentrate or point of use composition). The second polishing composition may advantageously include acetic acid.

Disclosed polishing compositions further include a topography control agent. In preferred embodiments, the topography control agent is a tertiary amine (a compound in which the nitrogen atom is directly bonded to three carbon atoms). A most preferred topography control agent is bis tris methane (also referred to herein as bis tris). It has been surprisingly found that the use of bis tris methane can improve the SiCN removal rate and also significantly improve topography control during the CMP operation. Acetic acid has also been found to be a suitable topography control agent in certain acidic embodiments (e.g., having a pH in a range from about 2.5 to about 4).

The disclosed embodiments may include substantially any suitable amount of the topography control agent (e.g., the bis tris methane). The polishing composition may include about 50 ppm by weight or more of the topography control agent at point of use (e.g., about 100 ppm or more, about 200 ppm or more, about 400 ppm or more, or about 600 ppm or more). The polishing composition may also include about 5000 ppm by weight or less of the topography control agent at point of use (e.g., about 2000 ppm or less, about 1600 ppm or less, about 1400 ppm or less, or about 1200 ppm or less). Accordingly, the point of use amount of the topography control agent in the polishing composition may be in a range bounded by any two of the above endpoints. For example, the amount of topography control agent in the polishing composition may be in a range from about 50 ppm by weight to about 5000 ppm by weight (e.g., from about 100 ppm to about 2000 ppm, from about 200 ppm to about 1600 ppm, from about 400 ppm to about 1400 ppm, or from about 600 ppm to about 1200 ppm).

The polishing composition may optionally further include a biocide. The biocide may include any suitable biocide, for example an isothiazolinone biocide. The amount of biocide in the polishing composition typically is in a range from about 1 ppm to about 50 ppm at point of use or in a concentrate, and preferably from about 1 ppm to about 20 ppm.

The polishing composition may be prepared using any suitable techniques, many of which are known to those skilled in the art. The polishing composition may be prepared in a batch or continuous process. Generally, the polishing composition may be prepared by combining the components thereof in any order. The term “component” as used herein includes the individual ingredients (e.g., including the silica particles, the topography control agent, and any other optional compounds).

For example, the topography control agent may be added directly to a dispersion including a suspended silica abrasive. The components may be blended together using any suitable techniques for achieving adequate mixing. Such blending/mixing techniques are well known to those of ordinary skill in the art. The polishing composition may advantageously be supplied as a one-package system including the comprising a colloidal silica having the above described physical properties and other optional components.

The polishing composition of the invention may also be provided as a concentrate which is intended to be diluted with an appropriate amount of water prior to use. In such an embodiment, the polishing composition concentrate may include the abrasive particles, the topography control agent and other optional components in amounts such that, upon dilution of the concentrate with an appropriate amount of water, each component of the polishing composition will be present in the polishing composition in an amount within the appropriate ranges recited above for each component. For example, each of the components may each be present in the polishing composition in an amount that is about 2 times (e.g., about 3 times, about 4 times, about 5 times, or about 10 times) greater than the point of use concentrations recited above for each component so that, when the concentrate is diluted with an equal volume (or mass) of water (e.g., 2 equal volumes (or masses) of water, 3 equal volumes (or masses) of water, 4 equal volumes (or masses) of water, or 9 equal volumes (or masses) of water), each component will be present in the polishing composition in an amount within the ranges set forth above for each component. Furthermore, as will be understood by those of ordinary skill in the art, the concentrate may contain an appropriate fraction of the water present in the final polishing composition in order to ensure that other components are at least partially or fully dissolved in the concentrate.

In one example embodiment, a polishing concentrate may include a water based liquid carrier, at least 10 weight percent of anionic silica particles, a bis tris methane topography control agent, and have a pH in a range from about 4 to about 7 (or from about 5 to about 6). The polishing concentrate may be diluted with deionized water prior to use to obtain a polishing composition including appropriate concentrations of the anionic silica particles and the bis tris methane.

In another example embodiment, a polishing concentrate may include a water based liquid carrier, at least 10 weight percent of anionic silica particles, acetic acid, and have a pH in a range from about 2.5 to about 4 (or from about 3 to about 4). The polishing concentrate may be diluted with deionized water prior to use to obtain a polishing composition including appropriate concentrations of the anionic silica particles.

The polishing method of the invention is particularly suited for use in conjunction with a chemical mechanical polishing (CMP) apparatus. Typically, the apparatus includes a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention and then the polishing pad moving relative to the silicon carbonitride layer on the substrate, so as to abrade at least a portion of the silicon carbonitride layer and thereby polish the substrate.

A substrate can be planarized or polished with the chemical mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, co-formed products thereof, and mixtures thereof.

It will be understood that the disclosure includes numerous embodiments. These embodiments include, but are not limited to, the following embodiments.

In a first embodiment a chemical mechanical polishing composition for polishing a silicon carbide nitride layer includes an aqueous based liquid carrier; anionic colloidal silica particles dispersed in the liquid carrier; bis tris methane; and a pH in a range from about 4 to about 7.

A second embodiment may include the first embodiment wherein the anionic colloidal silica particles have a zeta potential in the polishing composition of greater than about negative 10.

A third embodiment may include any one of the first through second embodiments comprising from about 1 weight percent to about 6 weight percent of the anionic colloidal silica abrasive particles.

A fourth embodiment may include any one of the first through third embodiments comprising from about 2 weight percent to about 4 weight percent of the anionic colloidal silica abrasive particles.

A fifth embodiment may include any one of the first through fourth embodiments wherein the anionic colloidal silica abrasive particles have an average particle size of less than 100 nm.

A sixth embodiment may include any one of the first through fifth embodiments wherein the anionic colloidal silica abrasive particles have an average particle size in a range from about 60 to about 80 nm.

A seventh embodiment may include any one of the first through sixth embodiments comprising from about 200 ppm to about 2000 ppm by weight of the bis tris methane.

An eighth embodiment may include any one of the first through seventh embodiments comprising from about 600 ppm to about 1200 ppm by weight of the bis tris methane.

A ninth embodiment may include any one of the first through eighth embodiments having a pH from about 5 to about 6.

A tenth embodiment may include any one of the first through ninth embodiments comprising from about 1 weight percent to about 6 weight percent of the anionic colloidal silica abrasive particles; from about 200 ppm to about 2000 ppm by weight of the bis tris methane; and wherein the anionic colloidal silica abrasive particles have an average particle size of less than 100 nm.

An eleventh embodiment may include any one of the first through tenth embodiments comprising from about 2 weight percent to about 4 weight percent of the anionic colloidal silica abrasive particles; from about 600 ppm to about 1200 ppm by weight of the bis tris methane; wherein the anionic colloidal silica abrasive particles have an average particle size in a range from about 60 to about 80 nm; and wherein the composition has a pH from about 5 to about 6.

In a twelfth embodiment a chemical mechanical polishing composition for polishing a silicon carbide nitride layer includes an aqueous based liquid carrier; anionic colloidal silica particles dispersed in the liquid carrier; acetic acid; and a pH in a range from about 2.5 to about 4.

A thirteenth embodiment may include the twelfth embodiment wherein the anionic colloidal silica particles have a zeta potential in the polishing composition of greater than about negative 10.

A fourteenth embodiment may include any one of the twelfth through the thirteenth embodiments comprising from about 1 weight percent to about 6 weight percent of the anionic colloidal silica abrasive particles.

A fifteenth embodiment may include any one of the twelfth through the fourteenth embodiments comprising from about 2 weight percent to about 4 weight percent of the anionic colloidal silica abrasive particles.

A sixteenth embodiment may include any one of the twelfth through the fifteenth embodiments wherein the anionic colloidal silica abrasive particles have an average particle size of less than 100 nm.

A seventeenth embodiment may include any one of the twelfth through the sixteenth embodiments wherein the anionic colloidal silica abrasive particles have an average particle size in a range from about 60 to about 80 nm.

An eighteenth embodiment may include any one of the twelfth through the seventeenth embodiments having a pH from about 3 to about 4.

A nineteenth embodiment may include any one of the twelfth through the eighteenth embodiments comprising from about 1 weight percent to about 6 weight percent of the anionic colloidal silica abrasive particles and wherein the anionic colloidal silica abrasive particles have an average particle size of less than 100 nm.

A twentieth embodiment may include any one of the twelfth through the nineteenth embodiments comprising from about 2 weight percent to about 4 weight percent of the anionic colloidal silica abrasive particles; herein the anionic colloidal silica abrasive particles have an average particle size in a range from about 60 to about 80 nm; and wherein the composition has a pH from about 3 to about 4.

In a twenty-first embodiment a method of chemical mechanical polishing a substrate having at least one silicon carbonitride layer includes (a) contacting the substrate with any one of the polishing compositions disclosed in the first through the twentieth embodiments; (b) moving the polishing composition relative to the substrate; and (c) abrading the substrate to remove a portion of the silicon carbonitride layer from the substrate and thereby polish the substrate.

The following examples further illustrate the invention but, of course, should not be construed as in any way limiting its scope.

### Example 1

This example demonstrates the effect of anionic colloidal silica particle loading and average size on the removal rate of SiCN and silicon oxide. Six polishing compositions were evaluated in this example. Each polishing composition included anionic colloidal silica particles, 1500 ppm by weight acetic acid, 75 ppm Kordex MLX biocide at a pH of 3.5. The anionic colloidal silica particles had zeta potentials between negative 36 and negative 39 mV in the compositions. The colloidal silica in compositions 1A and 1D had an average particle size of 70 nm. The colloidal silica in compositions 1B and 1E had an average particle size of 100 nm. The colloidal silica in compositions 1C and 1F had an average particle size of 120 nm. Compositions 1A-1C included 1 weight percent anionic colloidal silica and compositions 1D-1F included 6 weight percent anionic colloidal silica.

SiCN wafers and FCVD silicon oxide wafers (available from Silyb) were polishing for 60 seconds on a GNP POLI-500 polishing tool at a platen speed of 113 rpm, a head speed of 87 rpm, a downforce of 2 psi, and slurry flow rate of 150 ml/min. Blanket SiCN and FCVD oxide rates are shown in Table 1.

TABLE 1

| | Particle Size | Silica Content | SiCN RR | FCVD Ox RR |
|---|---|---|---|---|
| Composition | (nm) | (wt. %) | (Å/min) | (Å/min) |
| 1A | 70 | 1 | 1115 | 50 |
| 1B | 100 | 1 | 520 | 134 |
| 1C | 120 | 1 | 188 | 60 |
| 1D | 70 | 6 | 1097 | 237 |
| 1E | 100 | 6 | 432 | 268 |
| 1F | 120 | 6 | 205 | 182 |

As is readily apparent from the results set forth in Table 1, the highest SiCN removal rates and the highest SiCN to FCVD Ox selectivity is achieved using colloidal silica having an average particle size of 70 nm. In this composition, the SiCN removal rate is largely unaffected by the silica content while the FCVD Ox appears to increase with increasing silica content.

### Example 2

This example demonstrates the effect of pH and additive type on the removal rate of SiCN and silicon oxide. Nine polishing compositions were evaluated in this example. Each polishing composition included 1 weight percent anionic colloidal silica particles having an average particle size of 70 nm and 100 ppm Kordex MLX biocide. Compositions 2A-2E further included 1500 ppm by weight acetic acid. Compositions 2F-2I further included 872 ppm by weight bis tris methane. The composition pH values ranged from 2.3 to 7 as indicated in Table 2. The anionic colloidal silica particles had zeta potentials between negative 36 and negative 39 mV in the composition.

SiCN wafers and FCVD silicon oxide] wafers were polishing for 60 seconds on a GNP POLI-500 polishing tool at a platen speed of 113 rpm, a head speed of 87 rpm, a downforce of 1 psi, and slurry flow rate of 150 ml/min. Blanket SiCN and FCVD oxide rates are shown in Table 2.

TABLE 2

| | | | SiCN RR | FCVD Ox RR | |
|---|---|---|---|---|---|
| Composition | pH | Additive | (Å/min) | (Å/min) | SiCN:FCVD |
| 2A | 2.3 | Acetic | 1302 | 81 | 16 |
| 2B | 3 | Acetic | 1150 | 51 | 23 |
| 2C | 3.5 | Acetic | 1085 | 29 | 37 |
| 2D | 4.2 | Acetic | 1073 | 32 | 34 |
| 2E | 5.5 | Acetic | 812 | 44 | 18 |
| 2F | 5.5 | Bis Tris | 1083 | 8 | 135 |
| 2G | 6 | Bis Tris | 895 | 8 | 112 |
| 2H | 6.5 | Bis Tris | 593 | 19 | 31 |
| 2I | 7 | Bis Tris | 356 | 13 | 27 |

As is readily apparent from the data set forth in Table 2, the SiCN removal rates generally decrease with increasing pH. Compositions including bis tris methane were also observed to have an improved SiCN removal rate, reduced FCVD oxide removal rate, and significantly improved SiCN:FCVD selectivity as compared to compositions including acetic acid (particularly at pH 5.5 and 6).

### Example 3

This example demonstrates the effectiveness of the disclosed compositions on patterned wafer erosion performance. Eight polishing compositions were evaluated in this example. Compositions 3A through 3H were identical to compositions 2A through 2H described above in Example 2.

For compositions 3A to 3E, SiCN patterned wafers were polished for 120 seconds and then an additional 30 second overpolish to fully clear the wafer. For compositions 3F to 3H, SiCN patterned wafers were polished for 120 seconds and then an additional 120 second overpolish to fully clear the wafer. Polishing was performed on a GNP POLI-500 polishing tool at a platen speed of 113 rpm, a head speed of 87 rpm, a downforce of 1 psi, and slurry flow rate of 150 ml/min. Oxide erosion was evaluated at a number of sites of varying pitch and width (sites 1, 2, 3, and 4 in Table 3). The oxide erosion performance at each site was combined and summarized on an A, B, C scale with A representing the lowest erosion (the most favorable performance), C representing the highest erosion (the least favorable performance), and B representing a mid-range performance.

TABLE 3

| | | | Oxide Erosion (Å) | | | |
|---|---|---|---|---|---|---|
| Composition | pH | Additive | Site 1 | Site 2 | Site 3 | Site 4 |
| 3A | 2.3 | Acetic | B | C | B | B |
| 3B | 3 | Acetic | B | B | B | B |
| 3C | 3.5 | Acetic | B | B | B | A |
| 3D | 4.2 | Acetic | C | B | C | B |
| 3E | 5.5 | Acetic | C | B | C | C |
| 3F | 5.5 | Bis Tris | B | A | B | A |
| 3G | 6 | Bis Tris | A | A | A | A |
| 3H | 6.5 | Bis Tris | A | B | A | A |

As is apparent from the results set forth in Table 3, compositions 3F, 3G, and 3H including the bis tris methane topography control agent consistently achieved superior oxide erosion performance. It is further evident from Examples 2 and 3 that compositions 3F, 3G, and 3H (2F, 2G, and 2H) are superior in that they provide high SiCN removal rate, low FCVD oxide removal rate, and the most favorable topography. Moreover, compositions 3B and 3C were also observed to achieve favorable erosion performance. It is further evident from Examples 2 and 3 that compositions 3B and 3C (2B and 2C) also provide high SiCN removal rate in addition to favorable topography Given the high removal rate achieved using these compositions it will be understood that compositions 3B and 3C may advantageously provide process flexibility and that the erosion performance may be further improved by adjusting various process parameters (such as platen speed and downforce).

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical mechanical polishing composition for polishing a silicon carbide nitride layer, the composition comprising:
an aqueous based liquid carrier;
anionic colloidal silica particles dispersed in the liquid carrier;
bis tris methane; and
a pH in a range from about 4 to about 7.

2. The composition of claim 1, wherein the anionic colloidal silica particles have a zeta potential in the polishing composition of greater than about negative 10.

3. The composition of claim 1, comprising from about 1 weight percent to about 6 weight percent of the anionic colloidal silica abrasive particles.

4. The composition of claim 1, comprising from about 2 weight percent to about 4 weight percent of the anionic colloidal silica abrasive particles.

5. The composition of claim 1, wherein the anionic colloidal silica abrasive particles have an average particle size of less than 100 nm.

6. The composition of claim 1, wherein the anionic colloidal silica abrasive particles have an average particle size in a range from about 60 to about 80 nm.

7. The composition of claim 1, comprising from about 200 ppm to about 2000 ppm by weight of the bis tris methane.

8. The composition of claim 1, comprising from about 600 ppm to about 1200 ppm by weight of the bis tris methane.

9. The composition of claim 1, having a pH from about 5 to about 6.

10. The composition of claim 1, comprising:
from about 1 weight percent to about 6 weight percent of the anionic colloidal silica abrasive particles;
from about 200 ppm to about 2000 ppm by weight of the bis tris methane; and
wherein the anionic colloidal silica abrasive particles have an average particle size of less than 100 nm.

11. The composition of claim 1, comprising:
from about 2 weight percent to about 4 weight percent of the anionic colloidal silica abrasive particles;
from about 600 ppm to about 1200 ppm by weight of the bis tris methane;
wherein the anionic colloidal silica abrasive particles have an average particle size in a range from about 60 to about 80 nm; and
wherein the composition has a pH from about 5 to about 6.

12. A chemical mechanical polishing composition for polishing a silicon carbide nitride layer, the composition comprising:
an aqueous based liquid carrier;
anionic colloidal silica particles dispersed in the liquid carrier;
acetic acid; and
a pH in a range from about 2.5 to about 4.

13. The composition of claim 12, wherein the anionic colloidal silica particles have a zeta potential in the polishing composition of greater than about negative 10.

14. The composition of claim 12, comprising from about 1 weight percent to about 6 weight percent of the anionic colloidal silica abrasive particles.

15. The composition of claim 12, comprising from about 2 weight percent to about 4 weight percent of the anionic colloidal silica abrasive particles.

16. The composition of claim 12, wherein the anionic colloidal silica abrasive particles have an average particle size of less than 100 nm.

17. The composition of claim 12, wherein the anionic colloidal silica abrasive particles have an average particle size in a range from about 60 to about 80 nm.

18. The composition of claim 12, having a pH from about 3 to about 4.

19. The composition of claim 12, comprising:
from about 1 weight percent to about 6 weight percent of the anionic colloidal silica abrasive particles; and
wherein the anionic colloidal silica abrasive particles have an average particle size of less than 100 nm.

20. The composition of claim 12, comprising:
from about 2 weight percent to about 4 weight percent of the anionic colloidal silica abrasive particles;
wherein the anionic colloidal silica abrasive particles have an average particle size in a range from about 60 to about 80 nm; and
wherein the composition has a pH from about 3 to about 4.

21. A method of chemical mechanical polishing a substrate having at least one silicon carbonitride layer, the method comprising:
(a) contacting the substrate with the polishing composition of claim 1;
(b) moving the polishing composition relative to the substrate; and
(c) abrading the substrate to remove a portion of the silicon carbonitride layer from the substrate and thereby polish the substrate.

22. A method of chemical mechanical polishing a substrate having at least one silicon carbonitride layer, the method comprising:
(a) contacting the substrate with the polishing composition of claim 12;
(b) moving the polishing composition relative to the substrate; and
(c) abrading the substrate to remove a portion of the silicon carbonitride layer from the substrate and thereby polish the substrate.
